(19) United States
(12) Patent Application Publication
(10) Pub. No.: US 2025/0139316 A1
(43) Pub. Date: May 1, 2025

(54) PROCESSOR-BASED SYSTEM AND METHOD FOR BUILDING SYSTEM OPTIMIZATION

(71) Applicant: UNITED STATES GYPSUM COMPANY, Chicago, IL (US)

(72) Inventor: Frank POSPISIL, Oak Park, IL (US)

(21) Appl. No.: 18/897,647

(22) Filed: Sep. 26, 2024

Related U.S. Application Data
(60) Provisional application No. 63/593,155, filed on Oct. 25, 2023.

(51) Int. Cl. G06F 30/13

(52) U.S. Cl. CPC G06F 30/13

(57) ABSTRACT

A method of optimizing a building layout using a processor and memory comprises: receiving, by a model, inputs including a preliminary layout and one or more building factor priorities; processing, using the model, the inputs to generate an optimized layout; and providing the optimized output and/or a recommendation based on the optimized output to the operator terminal.

### REFERENCE TO RELATED APPLICATIONS

This application claims the benefit of U.S. Provisional Patent Application Ser. No. 63/593,155, filed Oct. 25, 2023, which application is incorporated by reference herein in its entirety.

### FIELD

The present disclosure relates to processor-assisted architectural design. More specifically, the present disclosure relates to processor-based methods and systems for optimizing an architectural design based on received parameters.

### BACKGROUND

Currently, building designers (individuals or teams) create or generate building designs based upon experience and current knowledge. However, as the scope of such experience and knowledge can widely vary and decisions based on such experience may be subjective to some degree, resulting building designs may not be optimized but instead may vary significantly, e.g., depending on the designer, as opposed to being based on maximizing efficiency in a more coherent, consistent, or methodical fashion.

For example, parts and sections of a structure that make up a building may typically be selected based on familiarity and/or common use. As an illustration, while there may be many one-hour non-load bearing walls that are available for a building design, an architect may regularly select a wall based simply upon familiarity with the design and its common use, and not, say, because it would maximize floor space or because the components of the wall are the least expensive or are readily available in the area of the country in which the building is to be built.

Some methods for generating or evaluating plans or designs have been disclosed. For example, U.S. Pat. No. 11,468,206 to Yeh discloses generating Building Information Models (BIMs) and renderings. US Pat. Pub. 2022/0198097 to Bandera discloses generating structural system designs. U.S. Pat. No. 8,954,297 to Teller discloses an interface for a “design engine.” U.S. Pat. No. 11,263,363 to Gifford, U.S. Pat. No. 11,436,386 to Motahar, and 11,714,940 to Sheehan, US Patent Publication No. 2023/0274046 to Zorzet, and international patent publication WO 2022/256460 disclose evaluating plans or designs.

However, such methods have to date been insufficient.

### SUMMARY

According to one aspect of the disclosed embodiments, a method of optimizing a building layout using a processor and memory is provided, the method comprising: receiving, by a model, inputs including a preliminary layout and one or more building factor priorities; processing, using the model, the inputs to generate an optimized layout; and providing the optimized output and/or a recommendation based on the optimized output to the operator terminal.

According to another aspect of the disclosed embodiments, a processor-based architecture for optimizing a building layout is provided comprising: a model that receives, over a network from an operator terminal, inputs including a preliminary layout and one or more building factor priorities and generates an optimized layout; an evaluation module for evaluating the generated optimized layout based on the input building factor priorities; and an interface for receiving the inputs and for providing an output and/or a recommendation based on the optimized output to the operator terminal.

Other embodiments provide an apparatus for optimizing a building layout comprising: a processor; a memory; and machine-executable instructions stored in the memory for causing the processor to perform one or more methods as provided herein.

Other features and advantages of the invention will be apparent from the following specification taken in conjunction with the following figures.

### BRIEF DESCRIPTION OF THE DRAWINGS

The present disclosure will become more fully understood from the detailed description and the accompanying figure, wherein:

FIG. 1 shows an example data flow for a building optimization model architecture according to an example embodiment.

FIG. 2 shows an example method that may be performed by the building optimization model architecture.

FIG. 3A shows an example screenshot of an interface for receiving prioritized factors, which may be provided to an operator.

FIG. 3B shows an example screenshot of an interface for providing, e.g., uploading, a building layout.

FIG. 4 shows an example output screen for an operator terminal.

FIG. 5 shows an example network architecture in which example systems and methods may be implemented.

### DETAILED DESCRIPTION

While this invention is susceptible of embodiments in many different forms, there is shown in the drawings and will herein be described in detail preferred embodiments of the invention with the understanding that the present disclosure is to be considered as an exemplification of the principles of the invention and is not intended to limit the broad aspects of the invention to the embodiments illustrated.

Optimizing an architectural design, e.g., a building design, can provide a more efficient design, where such efficiency can be based on one or several parameters. Parameters can represent features to be optimized and/or constraints that are preferred or mandatory. Examples of parameters include, but are not limited to, cost, maximized footprint, or increased life safety. Multiple parameters often require a tradeoff (e.g., improved safety features can result in increased cost, etc.). This tradeoff may be considered by an operator as one or more priorities.

Example methods and systems can provide, among other things, a process by which an architectural design, e.g., a building or structure design, may be optimized based on a selected priority of factors. Embodiments disclosed herein provide, among other things, processor-based methods and systems for optimizing a received preliminary architectural design, such as but not limited to a preliminary building or structure design, based on one or more received parameters. The parameters include one or more (e.g., a list) or prioritized factors that may be requested by an example system and received from a user, e.g., via a network. Such building factors may be prioritized relative to one another. Some building factors may also include one or more mandatory constraints, e.g., a cost that is minimized but may not exceed $1M, or a floor space that is maximized but may not violate a local building code.

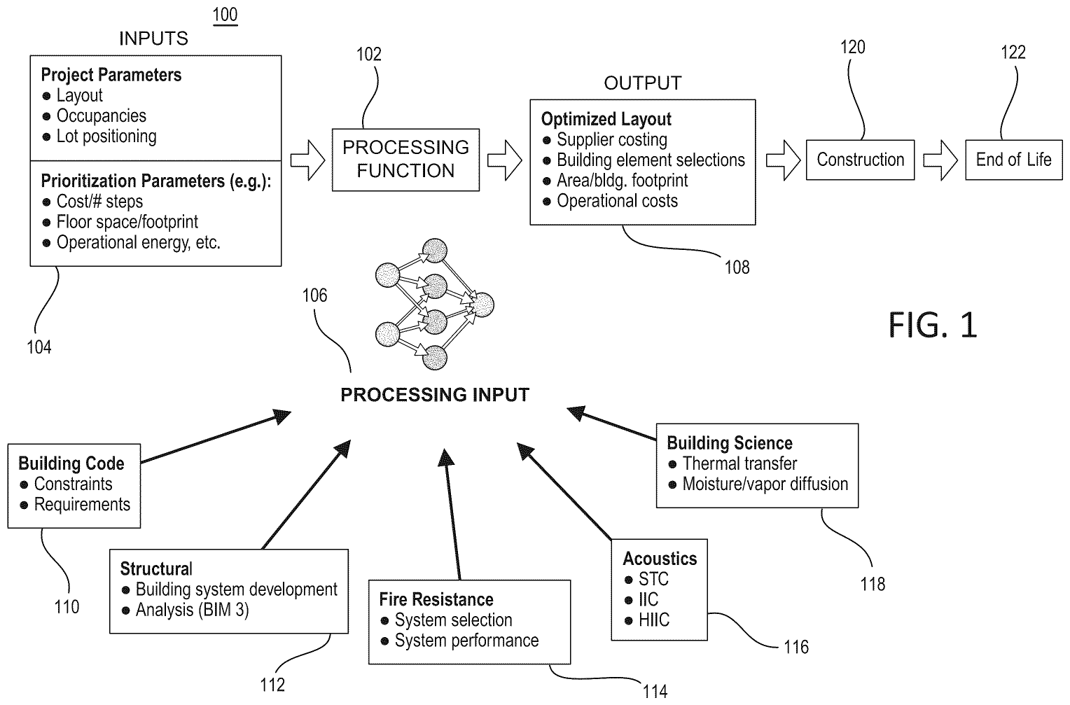

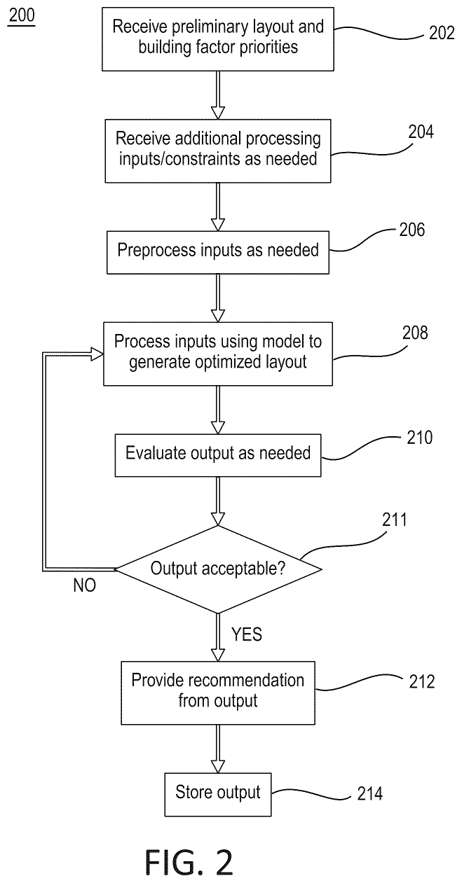

Turning now to the drawings, FIG. 1 shows an example data flow for a building optimization model architecture or system 100 according to an example embodiment, and FIG. 2 shows an example method 200 that may be performed by the building optimization model architecture. The building optimization model architecture 100 includes a processing function 102 that may be include or be embodied in a model. A model may be embodied in, as nonlimiting examples, a machine learning model such as but not limited to a deep learning model, a handcrafted model or specially configured model including one or more algorithms that may or may not be trainable or learned, or others, including combinations. Machine learning models may include, for instance, neural network models, encoder-decoder architectures, generative models, predictive models, or a combination, or other architectures that will be apparent, while handcrafted models may include one or more coded algorithms for processing inputs. The processing function 102, e.g., including the example model, may be a unitary model or may be modular, and may include one or more individual and separately configured and/or trainable modules for performing various building optimization related tasks. Modules may alternatively or additionally be trained together, e.g., end-to-end on an optimization task. Modules may also be provided for training and/or evaluating outputs of other modules. For example, the model may include a generative or predictive model for generating an optimized building design and an evaluation or discriminator model for evaluating the optimized building design. An evaluation model may be used to train (and/or be trained by) the generative model, similar to a generative adversarial network (GAN). Models or individual modules may additionally or alternatively be handcrafted in part or entirely. Modules may include one or more pretrained modules, such as but not limited to language models (e.g., large language models) for processing input features including tokens or text.

At step 202, the processing function 102 receives inputs 104, e.g., from an operator terminal or other source. The inputs 104 may include, for instance, a preliminary layout and one or more building factor priorities. An example preliminary layout may be represented by, for instance, project parameters for one or more of a building layout, occupancies, and/or lot positioning. A preliminary architectural design for the example input 104 may include, for instance, a building configuration, such as but not limited to a floor plan with parameters applied to all or a subset of (e.g., various) sections of the building. The parameters may be provided directly, provided indirectly, e.g., generated using an existing model, e.g., a building information model (BIM), or via a combination. An operator terminal may be provided, for instance, from a client device operatively connected to the processing function 102 over a network, connected directly or locally, or in other ways.

The example building factor priorities in the input 104 shown in FIG. 1 include or can be associated with one or more prioritization parameters such as cost/number of steps, floor space/footprint, and operational energy. However, this example list is not exhaustive. Nonlimiting example building factors that may be prioritized include:
Cost of construction
Number of construction steps
Time duration of construction (e.g., based on availability of materials and/or time needed to work with such materials)
Maximization of floor space
Footprint
Maximization of fire safety
Maximization of structural integrity (e.g., against seismic, blast, ballistic, and/or progressive collapse)
Energy efficiency
Thermal transfer
Acoustic performance

For receiving prioritized factors, the system 100 may present a list of available building factors to an operator, e.g., an owner or designer), in any suitable format, one or more of which may be interactive (checklist, bullet point, radio selection, text list, table, cells, icons for selection, slider, drag and drop interface, etc.). The received priorities for one, some, or all of the presented factors may be received in any suitable manner by the operator interfacing with the presented list. For instance, the system 100 may provide the priorities for display on an operator display of the operator terminal. Priorities may be embodied, presented, organized, or arranged in any suitable manner. As a nonlimiting example, priorities may be embodied in a rank or relative or ordinal priority, a cardinal number (whole number, percentage, value (e.g., “stars”), etc.) such that higher (or lower) cardinal numbers indicate a higher priority, or others, Default priorities may be assigned to factors that are not selected, either alone, or dependent on other prioritized factors. Default priorities may also be stored for particular operators, e.g., associated with a stored operator's profile, and retrieved for providing default prioritized factors.

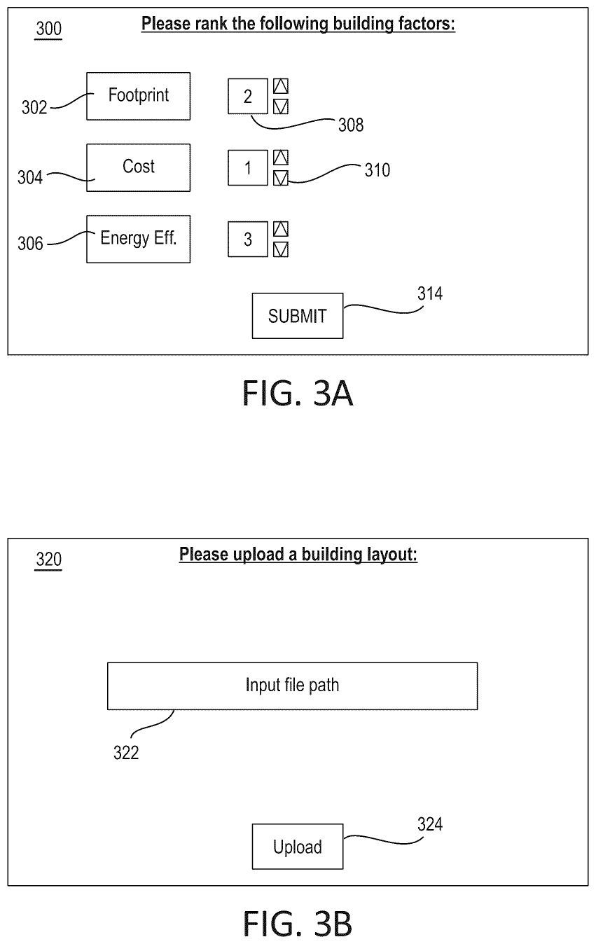

FIG. 3A shows an example screenshot of an interface 300 for receiving interactive prioritized factors, which may be provided to an operator, for instance, via a cloud portal, web portal, LAN portal, or other network architecture. The interface 300 may be provided, for instance, for display on an operator terminal (an example operator device). The example factors shown include: building footprint 302, which here is ranked “2” (out of 3 possible in this example, with 1 being highest), cost 304, which is ranked “1,” and energy efficiency 306, which is ranked “3” (or last, in this example). Rankings may be presented, for instance, via ranking field (e.g., box) 308. Alternatively, each factor could be assigned a number, e.g., from 1 to 10 or otherwise, shown on a slider, etc. A selection tool, such as but not limited to arrows 310, may be provided to allow the operator to edit a displayed priority ranking. A tool, e.g., a selection button 314, may be provided for submitting the operator's selected (and edited, as needed) prioritized factors.

FIG. 3B shows an example screenshot of an interface 320 for providing, e.g., uploading, a building layout. The interface 320 includes a file path input field (e.g., box) 322 for allowing an operator to input (e.g., select, enter via text, etc.) a file path where the building layout is located for uploading. A tool, e.g., a button 324, can be provided for allowing the operator to initiate uploading.

Referring again to FIGS. 1 and 2, at 204, the processing function 102 receives one or more additional processing inputs and/or constraints 106, if one or more of these were not already provided (e.g., previously stored in the system 100). The additional inputs/constraints 106 may be provided via the client device/operator terminal, provided within the system 100, provided from other devices connected to the system 100, or a combination. The additional processing inputs 106 may be used, for instance, to aid in generating an optimized building layout by providing one or more required features or constraints, and/or to evaluate generated optimized building layouts for various features or factors. Example parameters that may be provided via the additional processing inputs 106 include, but are not limited to, fire, structural, acoustic, and/or building ratings per code restrictions and/or requirements that may be available. Descriptors such as but not limited to preferred structural systems and finishes may also be provided for an overall building design and/or for one or more building sections. Example methods and systems can thus account for multiple, often competing priorities and/or constraints (fire resistance, particular building code constraints, thermal transfer, acoustics) for various building factors as well as the input priorities for one or more such factors, for the building as a whole and/or for individual sections thereof. For instance, the example additional processing inputs and/or constraints 106 shown in FIG. 1 include: building code constraints and requirements 110; structural building system development parameters and analysis tools (as shown, BIM 3) 112; fire resistance tools including system selection and system performance 114; acoustic tools including sound termination class (STC) 116, impact insulation class (IIC), and high-frequency impact insulation class (HIIC), and building science tools 118 such as for evaluating thermal transfer and moisture/vapor diffusion. Other additional processing inputs and/or constraints are possible.

The preliminary architecture design and the received prioritized factors input at 202, which each may be represented by one or more parameters or features, may be processed at step 208 by the model 102 using processor-enabled methods to generate an optimized building layout. Example processor-based systems may use one or more models, which may be provided via one or more modules. Machine learning models having learnable model parameters may be used in some example embodiments. Example machine learning models may include one or more neural networks. Machine learning models or individual modules may be pretrained or fine-tuned in whole or in part for one or more desired tasks such as an optimization task. Handcrafted or preconfigured models may be coded with one or more algorithms for processing the preliminary architecture design and the received prioritized factors. Handcrafted or preconfigured models may be combined with machine learning models in other embodiments.

The preliminary architecture and building factor priorities provided via input 104 may be received as one or more parameters or features. Inputs 104 alternatively or additionally may be preprocessed, e.g., at step 206, to extract parameters or features. Preprocessing, which may be but need not be based in part on the received additional processing constraints 106, may alternatively or additionally take place in whole or in part (offline or online) before being input to the model at 202.

As a nonlimiting example, the preliminary layout architecture may be segmented into any suitable set of sub-features, segments, or sections, according to any suitable criteria, or provided as a whole, and may be represented as one or more feature parameters, vectors (or tensors), and/or embeddings. Preprocessing may also include application of prior or determined knowledge to one or more features of the preliminary architecture design of the prioritized factors, such as may be provided via additional processing input 106 or otherwise to optimize efficiency (including training efficiency) of the model 102. One or more of the additional processing inputs 106 may be, but need not be, preprocessed to optimize their use by the model 102. For instance, a building code or fire code may be processed by a language model, e.g., a large language model, to extract useful features, e.g., for generating and/or evaluating an optimized layout. Preliminary architectures or additional information represented as images may be processed using suitable image processing algorithms to extract parameters or features. Parameters or features may be normalized or filtered as needed or to improve efficiency of the model 102. Features or parameters representing the prioritized factors, the preliminary layout architecture, and/or the additional information 106 may be encoded or embedded using any suitable encoder(s), which may be learnable. It is also possible that one or more inputs provided at input 104 and/or 106 are not used to generate the optimized layout but instead are used to evaluate the layout, in which case such inputs may or may not be preprocessed. Inputs may also be used to both generate and evaluate the layout, or to generate, but not evaluate the layout.

At 208, the processing function including the model 102 processes the inputs, e.g., input 104 and optionally input 106, to generate an optimized layout 108. It is also possible that one or more inputs provided at input 104 and/or 106 are not used to generate the optimized layout but instead are used to evaluate the layout, or used to generate the optimized layout, but not to evaluate the layout, in any combination. One or multiple optimized layouts may be generated in generating step 108. An optimized layout may be represented as one or more design parameters or features, and may be generated, e.g., using one or more predictive, regressive, or classifier models (e.g., including a decoder in an encoder-decoder architecture, a multilayer perceptron (MLP), feedforward network, recurrent network, and/or any other suitable output determination, having any number of layers including an input, output, and hidden layers), using a generative model, using a handcrafted model or modules thereof with one or more configured (e.g., preprogrammed) algorithms, and/or in other ways.

Optimizing an architecture (e.g., building) layout may include, for instance, updating (e.g., via prediction and/or generation of updated parameters or parameter adjustments) one or more of the layout parameters representing the preliminary layout provided in input 104, where the updated layout parameters can represent the optimized layout. The updated layout parameters may then be used to provide the optimized layout in any desired format. Alternatively or additionally, the processing function may be configured to generate a new optimized layout based on the input 104. An example optimized layout may be provided, e.g., via a building information model (BIM), output tables, generated images (e.g., computer aided design (CAD) images), or in any other suitable format.

The example optimized layout 108 may include and/or may be used to derive one or more features such as but not limited to a supplier cost, building element selections, an area/building footprint, and/or operational cost. The features may be generated in any suitable order from the processing function, e.g., model 102, and one or more features may optionally be generated in part by one or more algorithms downstream of the model. For instance, the model 102 may generate an optimized layout including one or more of the above output features with updated layout parameters. The optimized layout 108 may be used for one or more downstream activities such as but not limited to construction evaluations, analyses, or recommendations 120 and/or end-of-life evaluations, analyses, or recommendations 122.

The generated optimized layout or layouts may be processed by the processing function, e.g., evaluated in an evaluation step 210 using one or more evaluation functions, to determine other output features. As a nonlimiting example, the model 102 may generate an optimized layout with updated layout parameters including building element selections, and the optimized layout may be evaluated to determine outputs such as the estimated supplier cost, area/building footprint, and operational costs. One or more of the inputs provided at input 104 and/or 106 may be used to evaluate the optimized layout instead of or in addition to being used to generate the optimized layout.

At step 211, the processing function 102 may, but need not, determine whether the evaluated optimized output(s) is/are acceptable, e.g., whether it meets any required rules or conditions, falls within required constraints, and/or is consistent with the input priorities, e.g., completely or to a sufficient degree or amount, such that the output(s) may be provided or used for downstream tasks (such as but not limited to recommendations or generating estimates). If the evaluated optimized layout is not acceptable (under any evaluation criteria that may be provided), the processing function 102 may return to generating one or more new optimized layouts at step 208, which may be (re) evaluated at 210. This can provide, for instance, an iterative process for generating and evaluating optimized layouts. The processing function 102 may, but need not, provide further instructions, parameters, conditions, etc. for performing additional generating of optimized layouts, e.g., to improve efficiency or for other reasons. Such further instructions, parameters, conditions, etc. may also be preprocessed, if needed.

Evaluating generated optimized layouts (e.g., in evaluation step 210) may alternatively or additionally be used in some example embodiments for training the processing function 102, e.g., training a machine learning model therein. Example models 102 may be trained, for instance, using any suitable supervised, unsupervised, or semi-supervised learning method. Model parameters may be initialized using any suitable method (randomly, uniformly, based on prior knowledge, etc.). Training may include, for instance, processing batches or datasets including sample preliminary designs, sets of prioritized factors, and existing optimized designs, generating, determining, or predicting optimized designs, and updating parameters of the model based on a quantified difference from existing optimized designs, e.g., via backpropagation. As another example, the processing function including model 102 may be trained to optimize an objective function that considers the prioritized factors by updating parameters of the model. Other nonlimiting examples of model training include imitation learning and reinforcement learning. Training may be performed offline or online. Any suitable optimization algorithm may be used to optimize models.

As a nonlimiting example, one or more of the building factors, e.g., the factors in input 104, may be represented by one or more metrics, which may be evaluated, e.g., via the additional processing inputs at 106, via processing algorithms present in the model 102, via preprocessing algorithms, or in other ways. Example determinations of metrics for desired building factors will be appreciated by those of ordinary skill in the art.

For a particular building factor or factors, there may be an ideal or peak value or threshold value for a particular metric, such as a value or threshold for the metric that would be met if the building factor were substantially (e.g., practically) unconstrained or undiminished by other, competing building factors. This ideal or peak can be set to a fixed number or amount or even a lower threshold in practice, as is suitable for relevant conditions. For instance, a building cost could be set to a practical threshold or floor (or even zero as a theoretical minimum) based on input conditions. For acoustic factors, an IIC or HIIC rating may be set to an ideal value. Other examples will be apparent. One or more metrics may be, but need not be, combined for assessing particular building factors. For instance, if acoustic performance is a building factor for which a priority can be assigned, the performance may be based on one, a plurality, or an aggregation of metrics (STC, IIC, HIIC) as desired.

In some example methods, a higher priority for a building factor can be associated with a lower deviation or distance from an ideal or peak value for one or more metrics (which can be aggregated as desired) associated with that building factor relative to other building factors. Deviation or distance can be set in any suitable manner, e.g., as a percentage, by number of standard deviations, by difference or normalized difference, by Euclidean distance, or in other ways. In such example methods, a building design can be evaluated with respect to priorities of building factors by comparing the associated distances from ideal or peak values for metrics.

For instance, if a cost (loss) or optimization function is used to evaluate a generated optimized design, the cost (loss) or optimization function can include evaluated distances or deviations across various building factor metrics, with weight parameters for each factor being determined based on received priority. As another example, distances or deviations across various building factor metrics may be evaluated to determine an output priority ranking set for the building factor metrics, and this output priority ranking set may be compared to a received priority ranking set using any suitable metric or statistic. For building factors that are mandatory constraints, a weighting parameter for determining a loss may be sufficiently large (up to effectively infinite) in some examples to reject the solution and/or to force the model to move away from such solutions. Alternatively or additionally, a model may generate a plurality of candidate solutions (e.g., represented by sets of output parameters or ranges, by an output vector of values, by an output vector which may include one or more probabilities, etc.), a search for a solution may be conducted from the output using suitable search methods, and candidate solutions that fail to meet mandatory constraints may be rejected and others selected.

The optimized design can be output to the user at step 212, e.g., as a recommendation via the network 100, stored (in step 214), e.g., in memory, provided for display on a display, and/or used for further downstream actions, including but not limited those relating to construction 120 or end-of-life 122 considerations. Example downstream actions include, but are not limited to, ordering specific components, materials, parts, generating a parts list, a plan, a schedule, etc.

More than one optimized design may be generated, and multiple optimized designs may be presented as a list, arranged by any suitable ranking system (e.g., by top N priorities, by closeness to the received set of priorities, etc.). Generated optimized designs may be evaluated, e.g., in evaluation step 210 for compliance with one or more mandatory factors before being presented to the user.

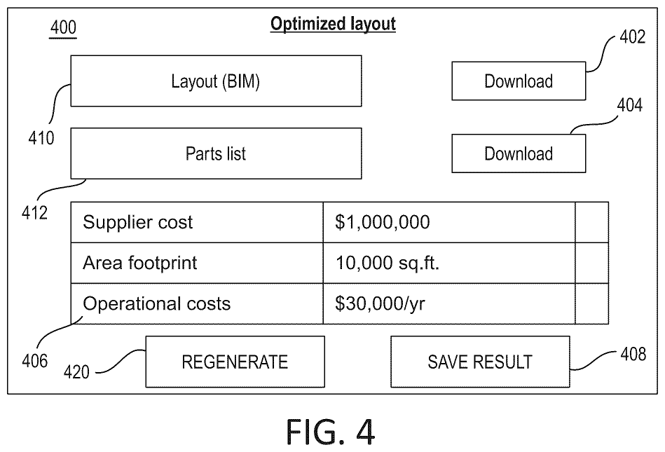

FIG. 4 shows an example output screen 400, e.g., for an operator terminal, which includes a link 402 for downloading the optimized layout, e.g., indicated at display tool 410, a link 404 for downloading a generated set of building element selections (parts list), e.g., indicated at display tool 412, and a table 406 indicating an estimated supplier cost, an estimated area footprint, and an estimated operational cost. A tool, e.g., button 408, can also be provided for saving the results (step 214), e.g., in a profile associated with the operator. The operator can accept the results and/or may request the generation of a new optimized layout, e.g., via a separate selection tool, e.g., “regenerate” button 420.

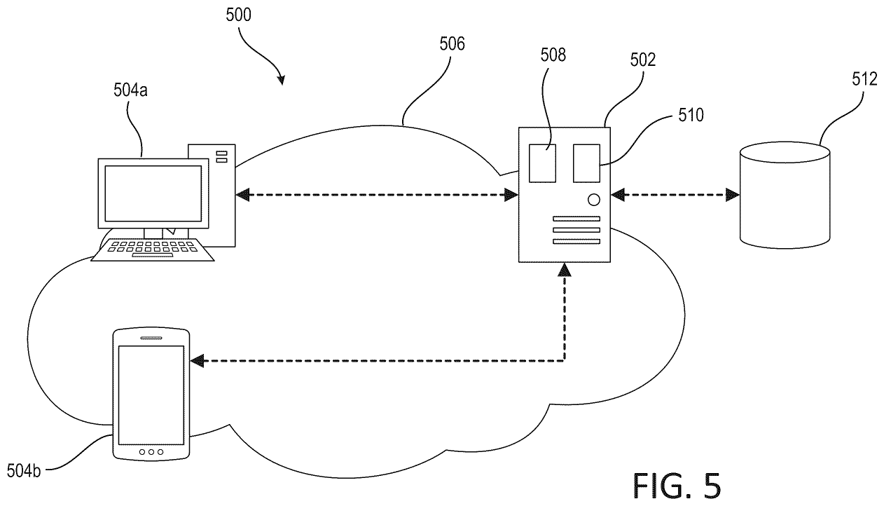

Example systems, methods, and embodiments may be implemented within a network architecture 500 such as illustrated in FIG. 5, which comprises a server 502 and one or more client devices 504 that communicate over a network 506 which may be wireless and/or wired, such as the Internet, for data exchange. The server 502 and the client devices 504a, 504b can each include a processor, e.g., processor 508 and a memory, e.g., memory 510 (shown by example in server 502), such as but not limited to random-access memory (RAM), read-only memory (ROM), hard disks, solid state disks, or other non-volatile storage media. Memory 510 may also be provided in whole or in part by external storage in communication with the processor 508.

The architecture 100 or processing function 102 shown in FIG. 1 or portions thereof may be embodied in the server 502 and/or one or more client devices 504. It will be appreciated that the processor 508 can include either a single processor or multiple processors operating in series or in parallel, and that the memory 510 can include one or more memories, including combinations of memory types and/or locations. Server 502 may also include, but are not limited to, dedicated servers, cloud-based servers, or a combination (e.g., shared). Storage, e.g., a database, may be embodied in suitable storage in the server 502, client device 504, a connected remote storage 512 (shown in connection with the server 502, but can likewise be connected to client devices), or any combination.

Client devices 504 may be any processor-based device, terminal, etc., and/or may be embodied in a client application executable by a processor-based device, etc. Client devices may be disposed within the server 502 and/or external to the server (local or remote, or any combination) and in communication with the server. Example client devices 504 include, but are not limited to, computers 504a, or mobile communication devices (e.g., smartphones, tablet computers, etc.) 504b, and other. Client devices 504 may be configured for sending data to and/or receiving data from the server 502, and may include, but need not include, one or more output devices, such as but not limited to displays, printers, etc. for displaying or printing results of certain methods that are provided for display by the server. Client devices may include combinations of client devices.

In an example training method, e.g., if the example model 102 is a machine learning model, the server 502 or client devices 504 may receive a dataset from any suitable source, e.g., from memory 510 (as nonlimiting examples, internal storage, an internal database, etc.), from external (e.g., remote) storage 512 connected locally, or over the network 506. The example training method can generate a trained model that can be likewise stored in the server (e.g., memory 510), client devices 504, external storage 512, or combination. In some example embodiments provided herein, training and/or inference may be performed offline or online (e.g., at run time), in any combination. Results can be output (e.g., displayed, transmitted, provided for display, printed, etc.) and/or stored for retrieving and providing on request.

In an example building optimization method (e.g., at inference or runtime) the server 502 may receive inputs, e.g., inputs 104, 106, from any suitable source, e.g., by local or remote input from a suitable interface, or from another of the server or client devices connected locally or over the network 506. The example processing function, e.g., model 102 can be likewise stored in the server (e.g., memory 510), external storage 512, or combination. In some example embodiments provided herein, training and/or performance may be performed offline or online (e.g., at run time), in any combination. Results can be output (e.g., displayed, transmitted, provided for display, printed, etc.) and/or stored for retrieving and providing on request.

Embodiments of the invention provide, among other things, a method of optimizing a building layout using a processor and memory, the method comprising: receiving, by a model, inputs including a preliminary layout and one or more building factor priorities; processing, using the model, the inputs to generate an optimized layout; and providing the optimized output and/or a recommendation based on the optimized output to the operator terminal. In addition to any or all of the above features in this paragraph, the method may further comprise receiving one or more additional inputs or constraints for generating or evaluating the optimized layout. In addition to any or all of the above features in this paragraph, the additional inputs or constraints may comprise one or more of building code constraints or requirements, structural system development or analysis tools, fire resistance system selection or system performance tools, acoustic metric evaluating tools, or building science evaluating tools. In addition to any or all of the above features in this paragraph, the method may further comprise preprocessing the inputs and/or the additional inputs. In addition to any or all of the above features in this paragraph, the model may comprise a machine learning model. In addition to any or all of the above features in this paragraph, the building factor priorities may comprise one or more of cost, number of steps, floor space, footprint, and operational energy. In addition to any or all of the above features in this paragraph, the preliminary layout may comprise a plurality of project parameters. In addition to any or all of the above features in this paragraph, the method may further comprise evaluating the generated optimized layout based on the input building factor priorities. In addition to any or all of the above features in this paragraph, receiving and providing may occur over a network.

Other embodiments of the invention provide, among other things, an apparatus for optimizing a building layout comprising: a processor; a memory; and machine-executable instructions stored in the memory for causing the processor to perform a method according to any of the methods set out in the previous paragraph.

Other embodiments of the invention provide, among other things, a processor-based architecture for optimizing a building layout comprising: a model that receives, over a network from an operator terminal, inputs including a preliminary layout and one or more building factor priorities and generates an optimized layout; an evaluation module for evaluating the generated optimized layout based on the input building factor priorities; and an interface for receiving the inputs and for providing an output and/or a recommendation based on the optimized output to the operator terminal. In addition to any or all of the above features in this paragraph, the architecture may further comprise a preprocessing module for preprocessing the inputs. In addition to any or all of the above features in this paragraph, the model may be a machine learning model. In addition to any or all of the above features in this paragraph, the preprocessing module may further process additional inputs or constraints for generating or evaluating the optimized layout. In addition to any or all of the above features in this paragraph, the additional inputs or constraints may comprise one or more of building code constraints or requirements, structural system development or analysis tools, fire resistance system selection or system performance tools, acoustic metric evaluating tools, or building science evaluating tools.

The foregoing description is merely illustrative in nature and is in no way intended to limit the disclosure, its application, or uses. The broad teachings of the disclosure may be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure may be implemented in and/or combined with features of any of the other embodiments, even if that combination is not explicitly described. It will be readily understood that the aspects of the present disclosure, as generally described herein, and illustrated in the figures, can be arranged, substituted, combined, separated, and designed in a wide variety of different configurations, all of which are explicitly contemplated herein. In other words, the described embodiments are not mutually exclusive, and permutations of one or more embodiments with one another remain within the scope of this disclosure. Other embodiments may be utilized, and other changes may be made, without departing from the scope of the subject matter presented herein.

Any of the above aspects and embodiments can be combined with any other aspect or embodiment as disclosed here in the Summary, Figures and/or Detailed Description sections, except where such combinations would be infeasible as will be appreciated by an artisan.

Each module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module. Each module may be implemented using code. The term code, as used above, may include software, firmware, and/or microcode, and may refer to programs, routines, functions, classes, data structures, and/or objects.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The systems and methods described in this application may be partially or fully implemented by a special purpose computer created by configuring a general purpose computer to execute one or more particular functions embodied in computer programs. The functional blocks, flowchart components, and other elements described above serve as software specifications, which may be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

As used in this specification and the claims, the singular forms “a,” “an” and “the” include plural referents unless the context clearly dictates otherwise.

Unless specifically stated or obvious from context, as used herein, the term “or” is understood to be inclusive and covers both “or” and “and.”

Unless specifically stated or obvious from context, as used herein, the term “about” is understood as within a range of normal tolerance in the art, for example within 2 standard deviations of the mean. About can be understood as within 20%, 19%, 18%, 17%, 16%, 15%, 14%, 13%, 12%, 11%, 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Unless specifically stated or obvious from context, as used herein, the terms “substantially all”, “substantially most of”, “substantially all of” or “majority of” encompass at least about 90%, 95%, 97%, 98%, 99% or 99.5%, or more of a referenced amount of a composition.

The entirety of each patent, patent application, publication and document referenced herein hereby is incorporated by reference. Citation of the above patents, patent applications, publications and documents is not an admission that any of the foregoing is pertinent prior art, nor does it constitute any admission as to the contents or date of these publications or documents. Incorporation by reference of these documents, standing alone, should not be construed as an assertion or admission that any portion of the contents of any document is considered to be essential material for satisfying any national or regional statutory disclosure requirement for patent applications. Notwithstanding, the right is reserved for relying upon any of such documents, where appropriate, for providing material deemed essential to the claimed subject matter by an examining authority or court.

Modifications may be made to the foregoing without departing from the basic aspects of the invention. Although the invention has been described in substantial detail with reference to one or more specific embodiments, those of ordinary skill in the art will recognize that changes may be made to the embodiments specifically disclosed in this application, and yet these modifications and improvements are within the scope and spirit of the invention. The invention illustratively described herein suitably may be practiced in the absence of any element(s) not specifically disclosed herein. Thus, for example, in each instance herein any of the terms “comprising”, “consisting essentially of”, and “consisting of” may be replaced with either of the other two terms. Thus, the terms and expressions which have been employed are used as terms of description and not of limitation, equivalents of the features shown and described, or portions thereof, are not excluded, and it is recognized that various modifications are possible within the scope of the invention. Embodiments of the invention are set forth in the following claims.

It will be appreciated that variations of the above-disclosed embodiments and other features and functions, or alternatives thereof, may be desirably combined into many other different systems or applications. Also, various presently unforeseen or unanticipated alternatives, modifications, variations, or improvements therein may be subsequently made by those skilled in the art which are also intended to be encompassed by the description above and the following claims.

What is claimed is:

1. A method of optimizing a building layout using a processor and memory, the method comprising:
receiving, by a model, inputs including a preliminary layout and one or more building factor priorities;
processing, using the model, the inputs to generate an optimized layout; and
providing the optimized output and/or a recommendation based on the optimized output to the operator terminal.

2. The method of claim 1, further comprising: receiving one or more additional inputs or constraints for generating or evaluating the optimized layout, wherein said additional inputs or constraints comprise one or more of building code constraints or requirements, structural system development or analysis tools, fire resistance system selection or system performance tools, acoustic metric evaluating tools, or building science evaluating tools.

3. The method of claim 1, further comprising: preprocessing the inputs and/or the additional inputs.

4. The method of claim 1, wherein the model comprises a machine learning model.

5. The method of claim 1, wherein the building factor priorities comprise one or more of cost, number of steps, floor space, footprint, and operational energy.

6. The method of claim 1, wherein the preliminary layout comprises a plurality of project parameters.

7. The method of claim 1, further comprising: evaluating the generated optimized layout based on the input building factor priorities.

8. The method of claim 1, wherein said receiving and said providing occur over a network.

9. A processor-based architecture for optimizing a building layout comprising:
a machine learning model that receives, over a network from an operator terminal, inputs including a preliminary layout and one or more building factor priorities and generates an optimized layout;
an evaluation module for evaluating the generated optimized layout based on the input building factor priorities; and
an interface for receiving the inputs and for providing an output and/or a recommendation based on the optimized output to the operator terminal.

10. The architecture of claim 9, further comprising: a preprocessing module for preprocessing the inputs.

11. The architecture of claim 10, wherein the preprocessing module further processes additional inputs or constraints for generating or evaluating the optimized layout, wherein said additional inputs or constraints comprise one or more of building code constraints or requirements, structural system development or analysis tools, fire resistance system selection or system performance tools, acoustic metric evaluating tools, or building science evaluating tools.

12. An apparatus for optimizing a building layout comprising:
a processor;
a memory; and
machine-executable instructions stored in the memory for causing the processor to perform a method comprising:
receiving, by a model, inputs including a preliminary layout and one or more building factor priorities;
processing, using the model, the inputs to generate an optimized layout; and
providing the optimized output and/or a recommendation based on the optimized output to the operator terminal.

13. The apparatus of claim 12, wherein the method further comprises: receiving one or more additional inputs or constraints for generating or evaluating the optimized layout, wherein said additional inputs or constraints comprise one or more of building code constraints or requirements, structural system development or analysis tools, fire resistance system selection or system performance tools, acoustic metric evaluating tools, or building science evaluating tools.

14. The apparatus of claim 12, wherein the method further comprises: preprocessing the inputs and/or the additional inputs.

15. The apparatus of claim 12, wherein the model comprises a machine learning model.

16. The apparatus of claim 12, wherein the building factor priorities comprise one or more of cost, number of steps, floor space, footprint, and operational energy.

17. The apparatus of claim 12, wherein the preliminary layout comprises a plurality of project parameters.

18. The apparatus of claim 12, wherein the method further comprises: evaluating the generated optimized layout based on the input building factor priorities.

19. The apparatus of claim 12, wherein said receiving and said providing occur over a network.
